(19) United States
(12) Patent Application Publication
(10) Pub. No.: US 2025/0350263 A1
(43) Pub. Date: Nov. 13, 2025

(54) STACKED BULK ACOUSTIC WAVE RESONATORS

(71) Applicant: Skyworks Solutions, Inc., Irvine, CA (US)

(72) Inventors: Eesa Rahimi, Greensboro, NC (US); Joshua James Caron, Summerfield, NC (US)

(21) Appl. No.: 19/201,268

(22) Filed: May 7, 2025

Related U.S. Application Data
(60) Provisional application No. 63/645,042, filed on May 9, 2024.
(60) Provisional application No. 63/645,036, filed on May 9, 2024.

(51) Int. Cl. H03H 9/58; H03H 9/02

(52) U.S. Cl. CPC H03H 9/585; H03H 9/02102; H03H 9/587; H03H 9/589

(57) ABSTRACT

A bulk acoustic wave device includes a first resonator having a first pair of electrodes and a first piezoelectric layer. The first pair of electrodes has a first top electrode and a first bottom electrode. The first piezoelectric layer is positioned between the first top electrode and a first bottom electrode. The device includes a second resonator having a second pair of electrodes and a second piezoelectric layer. The second pair of electrodes has a second top electrode and a second bottom electrode. The second piezoelectric layer is positioned between the second top electrode and a second bottom electrode. The first and second piezoelectric layers are positioned between the first bottom electrode and the second top electrode.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/645,042, filed May 9, 2024, titled “STACKED BULK ACOUSTIC WAVE RESONATORS,” and U.S. Provisional Patent Application No. 63/645,036, filed May 9, 2024, titled “BULK ACOUSTIC WAVE DEVICE WITH STACKED RESONATORS COUPLED IN PARALLEL WITH EACH OTHER” each of which is hereby incorporated by reference under 37 CFR 1.57 in its entirety.

### BACKGROUND

### Technical Field

The disclosed technology relates to acoustic wave devices. Embodiments of this disclosure relate to acoustic wave devices that include stacked bulk acoustic wave resonators.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

For BAW devices, achieving a high quality factor (Q) is generally desirable. Suppressing and/or attenuating spurious mode(s) in BAW devices is also generally desirable. There are technical challenges related to meeting performance specifications for BAW devices while also meeting the physical size specifications.

### SUMMARY OF CERTAIN EMBODIMENTS

The innovations described in the claims each have several aspects, no single one of which is solely responsible for its desirable attributes. Without limiting the scope of the claims, some prominent features of this disclosure will now be briefly described.

In some aspects, the techniques described herein relate to a bulk acoustic wave device including: a substrate; a first resonator supported by the substrate; and a second resonator over the first resonator and supported by the substrate such that the first resonator is positioned between the substrate and the second resonator; the second resonator electrically connected in parallel with the first resonator.

In some aspects, the techniques described herein relate to a bulk acoustic wave device wherein the first resonator includes a first pair of electrodes and a first piezoelectric layer, the first pair of electrodes having a first top electrode and a first bottom electrode, the first piezoelectric layer positioned between the first top electrode and a first bottom electrode, and the second resonator includes a second pair of electrodes and a second piezoelectric layer, the second pair of electrodes having a second top electrode and a second bottom electrode, the second piezoelectric layer positioned between the second top electrode and a second bottom electrode, the first and second piezoelectric layers positioned between the first bottom electrode and the second top electrode.

In some embodiments, the techniques described herein relate to a bulk acoustic wave device wherein the first bottom electrode and the second top electrode have a first polarity, and the first top electrode and the second bottom electrode have a second polarity opposite from the first polarity.

In some embodiments, the techniques described herein relate to a bulk acoustic wave device wherein a single layer includes the first top electrode and the second bottom electrode.

In some embodiments, the techniques described herein relate to a bulk acoustic wave device further including a temperature compensation layer coupled with the first piezoelectric layer, wherein the temperature compensation layer configured to dissipate heat generated in the first piezoelectric layer.

In some embodiments, the techniques described herein relate to a bulk acoustic wave device further including a third resonator positioned such that the second resonator is between the first resonator and the third resonator.

In some embodiments, the techniques described herein relate to a bulk acoustic wave device wherein the third resonator is electrically coupled in parallel with the second resonator.

In some embodiments, the techniques described herein relate to a bulk acoustic wave device wherein the first resonator has a first width and a first thickness, and the second resonator has a second width and a second thickness, a ratio between the first width and a total thickness of the first and second thicknesses is less than 50:1.

In some embodiments, the techniques described herein relate to a bulk acoustic wave device wherein the first width is less than 100 micrometers.

In some embodiments, the techniques described herein relate to a bulk acoustic wave device further including an intermediate layer between the first resonator and the second resonator.

In some aspects, the techniques described herein relate to a bulk acoustic wave device including: a first resonator including a first electrode, a second electrode, and a first piezoelectric layer between the first electrode and the second electrode; and a second resonator including the second electrode, a third electrode, and a second piezoelectric layer between the second electrode and the third electrode, the second electrode positioned between the first electrode and the third electrode.

In some embodiments, the techniques described herein relate to a bulk acoustic wave device wherein the first electrode and the third electrode have a first polarity, and the second electrode has a second polarity opposite from the first polarity.

In some embodiments, the techniques described herein relate to a bulk acoustic wave device further including a temperature compensation layer configured to dissipate heat generated in the first piezoelectric layer.

In some embodiments, the techniques described herein relate to a bulk acoustic wave device further including a third resonator positioned such that the second resonator is between the first resonator and the third resonator.

In some embodiments, the techniques described herein relate to a bulk acoustic wave device wherein the third resonator includes the third electrode, a fourth electrode, and a third piezoelectric layer between the third electrode and the fourth electrode.

In some embodiments, the techniques described herein relate to a bulk acoustic wave device wherein the third resonator is electrically coupled in parallel with the second resonator.

In some embodiments, the techniques described herein relate to a bulk acoustic wave device wherein the first resonator has a first width and a first thickness, and the second resonator has a second width and a second thickness, a ratio between the first width and a total thickness of the first and second thicknesses is less than 50:1.

In some embodiments, the techniques described herein relate to a bulk acoustic wave device wherein the first width is less than 100 micrometers.

In some embodiments, the techniques described herein relate to a bulk acoustic wave device further including a temperature compensation structure configured to dissipate heat generated by the first resonator and/or the second resonator.

In some aspects, the techniques described herein relate to an acoustic wave filter for filtering a radio frequency signal, the acoustic wave filter including: a bulk acoustic wave device of any preceding claim; and a plurality of additional acoustic wave resonators, the bulk acoustic wave device and the plurality of additional acoustic wave resonators configured to filter the radio frequency signal.

In some aspects, the techniques described herein relate to a bulk acoustic wave device including: a first resonator including a first pair of electrodes and a first piezoelectric layer, the first pair of electrodes having a first top electrode and a first bottom electrode, the first piezoelectric layer positioned between the first top electrode and a first bottom electrode; and a second resonator including a second pair of electrodes and a second piezoelectric layer, the second pair of electrodes having a second top electrode and a second bottom electrode, the second piezoelectric layer positioned between the second top electrode and a second bottom electrode, the first and second piezoelectric layers positioned between the first bottom electrode and the second top electrode.

In some embodiments, the techniques described herein relate to a bulk acoustic wave device wherein the first bottom electrode and the second top electrode have a first polarity, and the first top electrode and the second bottom electrode have a second polarity opposite from the first polarity.

In some embodiments, the techniques described herein relate to a bulk acoustic wave device wherein the first resonator is electrically connected in parallel with the second resonator.

In some embodiments, the techniques described herein relate to a bulk acoustic wave device wherein a single metal layer includes the first top electrode and the second bottom electrode.

In some embodiments, the techniques described herein relate to a bulk acoustic wave device wherein the first top electrode and the second bottom electrode are physically connected and contiguous.

In some embodiments, the techniques described herein relate to a bulk acoustic wave device wherein the first resonator is electrically connected in series with the second resonator.

In some embodiments, the techniques described herein relate to a bulk acoustic wave device further including an isolation layer between the first resonator and the second resonator.

In some embodiments, the techniques described herein relate to a bulk acoustic wave device wherein the first top electrode and the second bottom electrode are electrically isolated by an isolation layer.

In some embodiments, the techniques described herein relate to a bulk acoustic wave device further including a temperature compensation layer coupled with the first piezoelectric layer, wherein the temperature compensation layer configured to dissipate heat generated in the first piezoelectric layer.

In some embodiments, the techniques described herein relate to a bulk acoustic wave device further including a third resonator including a third pair of electrodes and a third piezoelectric layer, the second pair of electrodes having a third top electrode and a third bottom electrode, the third bottom electrode positioned between the second piezoelectric layer and the third piezoelectric layer.

In some embodiments, the techniques described herein relate to a bulk acoustic wave device wherein the first resonator, the second resonator, and the third resonator are electrically coupled in parallel with each other.

In some embodiments, the techniques described herein relate to a bulk acoustic wave device wherein the first resonator has a first width and a first thickness, and the second resonator has a second width and a second thickness, a ratio between the first width and a total thickness of the first and second thicknesses is less than 50:1.

In some embodiments, the techniques described herein relate to a bulk acoustic wave device wherein the first width is less than 100 micrometers.

In some aspects, the techniques described herein relate to a bulk acoustic wave device including: a first resonator including a first piezoelectric layer positioned between a first electrode and a second electrode; and a second resonator including a second piezoelectric layer positioned between the second electrode and a third electrode.

In some embodiments, the techniques described herein relate to a bulk acoustic wave device wherein the second piezoelectric layer, the second electrode, and the third electrode together define the second resonator.

In some embodiments, the techniques described herein relate to a bulk acoustic wave device further including a fourth electrode between the second piezoelectric layer and the second electrode, wherein the second piezoelectric layer, the third electrode, and the fourth electrode together define the second resonator.

In some embodiments, the techniques described herein relate to a bulk acoustic wave device further including an isolation layer between the second electrode and the fourth electrode.

In some embodiments, the techniques described herein relate to a bulk acoustic wave device further including a third resonator including a third piezoelectric layer positioned between the third electrode and a fourth electrode.

In some embodiments, the techniques described herein relate to a bulk acoustic wave device wherein the first resonator, the second resonator, and the third resonator are electrically coupled in parallel with each other.

In some embodiments, the techniques described herein relate to a bulk acoustic wave device wherein the third piezoelectric layer, the third electrode and the fourth electrode together define the third resonator.

In some aspects, the techniques described herein relate to an acoustic wave filter for filtering a radio frequency signal, the acoustic wave filter including: a bulk acoustic wave device of any preceding claim; and a plurality of additional acoustic wave resonators, the bulk acoustic wave device and the plurality of additional acoustic wave resonators configured to filter the radio frequency signal.

### BRIEF DESCRIPTION OF THE DRAWINGS

Embodiments of this disclosure will now be described, by way of non-limiting example, with reference to the accompanying drawings.

FIG. 1 is a schematic cross-sectional side view of a bulk acoustic wave (BAW) resonator.

FIG. 2A is a schematic cross-sectional side view of a BAW device according to an embodiment.

FIG. 2B is a schematic cross-sectional side view of a BAW device according to another embodiment.

FIG. 2C is a schematic circuit diagram of the BAW device of FIG. 2B.

FIG. 3A is a simulated stress distribution map of a first resonator.

FIG. 3B is a simulated stress distribution map of the first resonator and a second resonator stacked over the first resonator.

FIG. 3C is a simulated stress distribution map of the first resonator, the second resonator stacked over the first resonator, and a third resonator stacked over the second resonator.

FIG. 4A is a simulated displacement map of a first resonator.

FIG. 4B is a simulated displacement map of the first resonator and a second resonator stacked over the first resonator.

FIG. 4C is a simulated displacement map of the first resonator, the second resonator stacked over the first resonator, and a third resonator stacked over the second resonator.

FIG. 5A is a graph showing simulated frequency responses of three different BAW devices.

FIG. 5B is a scaled version of FIG. 5A.

FIGS. 6 and 7 show schematic perspective views of the BAW resonator and the BAW device of FIGS. 1 and 2.

FIG. 8 is a schematic cross-sectional side view of a BAW device according to an embodiment.

FIG. 9 is a schematic cross-sectional side view of a BAW device according to an embodiment.

FIG. 10 shows the BAW device as an example of a film bulk acoustic wave resonator (FBAR).

FIG. 11 shows the BAW device as an example of a BAW solidly mounted resonator (SMR).

FIG. 12A is a schematic diagram of a ladder filter that includes one or more BAW resonators according to an embodiment.

FIG. 12B is a schematic diagram of a band pass filter.

FIGS. 13A, 13B, 13C, and 13D are schematic diagrams of multiplexers that include a filter with one or more BAW resonators according to an embodiment.

FIGS. 14, 15, and 16 are schematic block diagrams of modules that include a filter with one or more BAW resonators according to an embodiment.

FIG. 17 is a schematic block diagram of a wireless communication device that includes a filter with one or more BAW resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other. The headings provided herein are for convenience only and are not intended to affect the meaning or scope of the claims.

A bulk acoustic wave (BAW) resonator can include a pair of electrodes and a piezoelectric layer positioned between the pair of electrodes. Reducing the lateral size (e.g., dimensions in a plane perpendicular to a thickness of the piezoelectric layer) of a BAW device can be significant in various applications, particularly in the context of modern electronic devices where miniaturization can be a key design consideration. A smaller lateral size allows for more compact and space-efficient designs, facilitating the integration of BAW devices into significantly smaller electronic components and systems. This, in turn, can contribute to improved overall device performance, higher operational frequencies, and enhanced energy efficiency. However, reducing the lateral size of BAW devices can be challenging. For example, reducing the lateral size while preserving optimal performance parameters, such as resonant frequency and energy transfer efficiency, can pose a significant technological challenge.

The lateral size of a BAW device can be reduced by doping the piezoelectric layer. However, lateral size reduction by introducing doping to piezoelectric lattice impacts the coupling of the resonator and reduces the quality of resonance. Also, doping ratio has a limitation in theory and practice. In theory, doping cannot exceed a limit because it can impact the piezo-electricity of the piezoelectric layer. In practice, producing highly doped piezoelectric layer can be difficult and/or costly. As a result, resonator size reduction by doping the piezoelectric layer has certain limits.

The BAW devices disclosed herein can reduce the lateral size without significantly degrading the coupling and quality of resonance. The principles and advantages disclosed herein have the potential to reduce the lateral resonator area as many times as desired.

Various embodiments disclosed herein relate to a BAW device with a reduced lateral size. The lateral size of the BAW devices according to various embodiments disclosed herein can be reduced by vertically stacking a plurality of resonators. A BAW resonator according to some embodiments can include a first resonator and a second resonator positioned over the first resonator. The first resonator can include a first pair of electrodes and a first piezoelectric layer. The first pair of electrodes has a first top electrode and a first bottom electrode. The piezoelectric layer is positioned between the first top electrode and a first bottom electrode. The second resonator can include a second pair of electrodes and a second piezoelectric layer. The second pair of electrodes have a second top electrode and a second bottom electrode. By vertically stacking the plurality of resonators, more BAW resonators can be provided in a given area or a BAW device with a reduced lateral size can be formed.

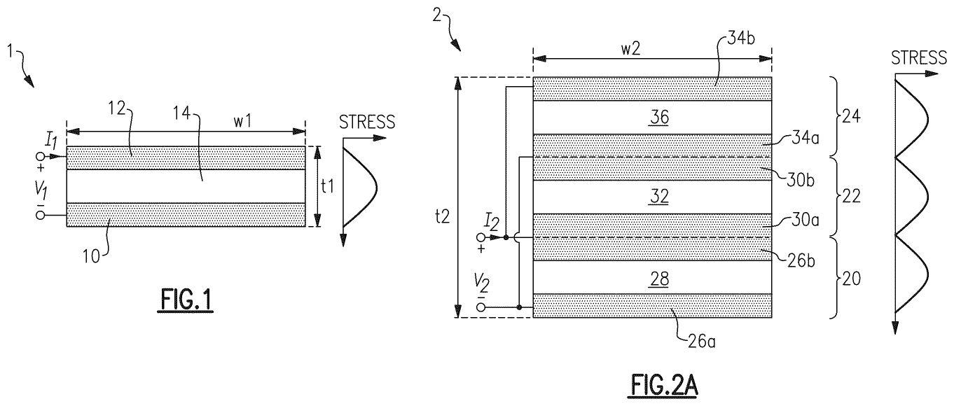

FIG. 1 is a schematic cross-sectional side view of a bulk acoustic wave (BAW) resonator 1. The BAW resonator 1 includes a first electrode 10, a second electrode 12, and a piezoelectric layer 14 between the first electrode 10 and the second electrode 12. The BAW resonator 1 can be referred to as a single resonator BAW device. In the illustrated example, the second electrode 12 can be an input electrode and the first electrode 10 can be an output electrode. An admittance Y0 of the BAW resonator 1 can be expressed in terms of the current I passing through the BAW resonator 1 and the voltage V applied across the resonator. The voltage V can induce mechanical vibration through the piezoelectric effect in the piezoelectric layer 14. In the illustrated BAW resonator 1, the admittance Y0 can be calculated by dividing the current I by the voltage V. FIG. 1 also shows a stress distribution plot that indicates a stress distribution within the BAW resonator 1 during operation of the BAW resonator 1 at resonance.

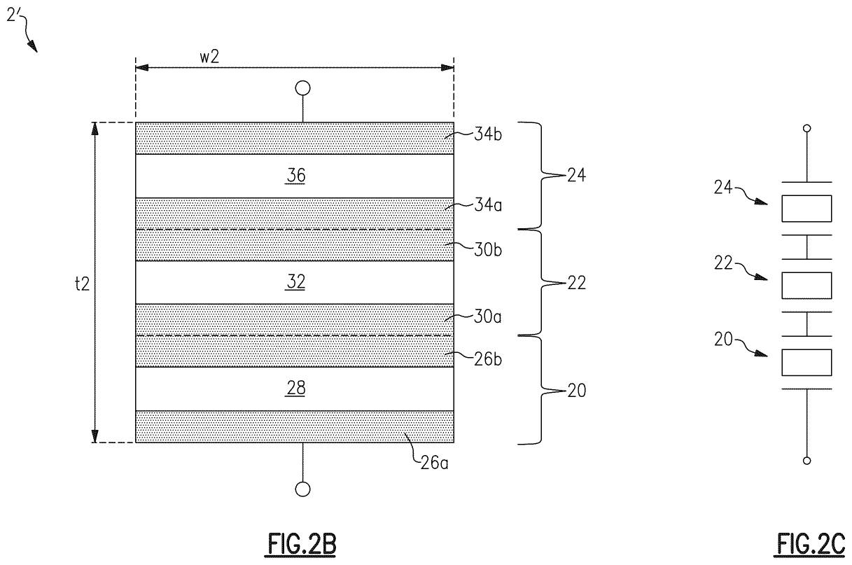

FIG. 2A is a schematic cross-sectional side view of a bulk acoustic wave (BAW) device 2 according to an embodiment. The BAW resonator 2 includes a plurality of stacked resonators. The BAW device 2 can include a first resonator 20, a second resonator 22, and a third resonator 24. Although three resonators are illustrated as an example in FIG. 2A, any suitable principle and advantages disclosed herein can be implemented with a BAW device that includes two or more resonators that are arranged in a manner as disclosed herein. FIG. 2A also shows a stress distribution plot that indicates a stress distribution within the BAW device 2 during operation of the BAW device 2.

Each resonator 20, 22, 24 can include a pair of electrodes and a piezoelectric layer. In some embodiments, thicknesses of the resonators 20, 22, 24 can be the same. In some other embodiments, the thicknesses of the resonators 20, 22, 24 can be different. Widths and areas of the resonators 20, 22, 24 can be identical. The same width and areas of the resonators 20, 22, 24 can be beneficial for reducing the risk of causing unwanted acoustic resonances outside of the main resonance of the BAW device 2. The first resonator 20 can include a first bottom electrode 26a, a first top electrode 26b, and a first piezoelectric layer 28 that is positioned between the first bottom electrode 26a and the first top electrode 26b. The second resonator 22 can include a second bottom electrode 30a, a second top electrode 30b, and a second piezoelectric layer 32 that is positioned between the second bottom electrode 30a and the second top electrode 30b. The third resonator 24 can include a third bottom electrode 34a, a third top electrode 34b, and a third piezoelectric layer 36 that is positioned between the third bottom electrode 34a and the third top electrode 34b. The first bottom electrode 26a, the first top electrode 26b, the second bottom electrode 30a, the second top electrode 30b, the third bottom electrode 34a, and the third top electrode 34b can be collectively referred to as electrodes of the BAW device 2. As illustrated, the first top electrode 26b and the second bottom electrode 30a can be physically connected and contiguous, the second top electrode 30b and the third bottom electrode 34a can be physically connected and contiguous. For example, the first top electrode 26b and the second bottom electrode 30a can be in direct contact with each other, and the second top electrode 30b and the third bottom electrode 34a can be in direct contact with each other. In some embodiments, a single metal layer can include the first top electrode 26b and the second bottom electrode 30a, and another single metal layer can include the second top electrode 30b and the third bottom electrode 34a.

The electrodes of the BAW device 2 can have a relatively high acoustic impedance. One or more of the electrodes of the BAW device 2 can include molybdenum (Mo), tungsten (W), ruthenium (Ru), chromium (Cr), iridium (Ir), platinum (Pt), or any suitable alloy and/or combination thereof. Two or more of the electrodes of the BAW device 2 can be formed of the same material in certain applications. The thicknesses of the electrodes of the BAW device 2 can be approximately the same in some applications. In some other applications, the thicknesses of the electrodes of the BAW device 2 can be different.

The piezoelectric layers 28, 32, 36 can include a suitable material such as, but not limited to, aluminum nitride (AlN), zinc oxide (ZnO), or lead zirconium titanate (PZT). In certain applications, the piezoelectric layers 28, 32, 36 can be an AlN layer. The piezoelectric material can be doped or undoped. For example, an AlN-based piezoelectric layer can be doped with any suitable dopant, such as scandium (Sc), chromium (Cr), magnesium (Mg), sulfur (S), yttrium (Y), silicon (Si), germanium (Ge), oxygen (O), hafnium (Hf), zirconium (Zr), titanium (Ti), or the like. In certain applications, the piezoelectric layers 28, 32, 36 can be AlN based layer doped with Sc. Doping the piezoelectric layers 28, 32, 36 can adjust the resonant frequency. Doping the piezoelectric layers 28, 32, 36 can increase the electromechanical coupling coefficient (kt²) of the BAW device 2. Doping to increase the kt² can be advantageous at higher frequencies where kt² can be degraded. In some embodiments, the piezoelectric layers 28, 32, 36 can include the same material or different materials.

In the illustrated embodiment, the first top electrode 26b, the second bottom electrode 30a, and the third top electrode 34b can be input electrodes and the first bottom electrode 26a, the second top electrode 30b, and the third bottom electrode 34a can be output electrodes. Thus, in the illustrated embodiment, the first to third resonators 20, 22, 24 are electrically coupled in parallel with each other. In some other embodiments, the first to third resonators 20, 22, 24 can be electrically coupled in series with each other (see FIGS. 2B and 2C).

FIG. 2B is a schematic cross-sectional side view of a bulk acoustic wave (BAW) device 2′ according to an embodiment. Unless otherwise noted, the components of the BAW device 2′ shown in FIG. 2B may be structurally and/or functionally the same as or generally similar to like components of other BAW devices disclosed herein. FIG. 2C is a schematic circuit diagram of the bulk acoustic wave (BAW) device 2′ of FIG. 2B. The resonators 20, 22, 24 are electrically coupled in series with each other.

An admittance Y1 of the first resonator 20 can be expressed in terms of the current I1 passing through the resonator 20 and the voltage V1 applied across the first resonator 20. The voltage V1 can induce mechanical vibration though the piezoelectric effect in the first piezoelectric layer 28. Similarly, admittance Y2 and admittance Y3 of the second resonator 22 and the third resonator 24 can be expressed in terms of the current I2, I3 passing through the second and third resonators 22, 24 and the voltage V2, V3 applied across the second and third resonators 22, 24. In some embodiments, the admittance Y1, the admittance Y2, and the admittance Y3 can be the same. When the thirst to third resonators 20, 22, 24 are electrically coupled in parallel with each other, an admittance Y of the BAW device 2 can be sum of the admittance Y1, the admittance Y2, and the admittance Y3.

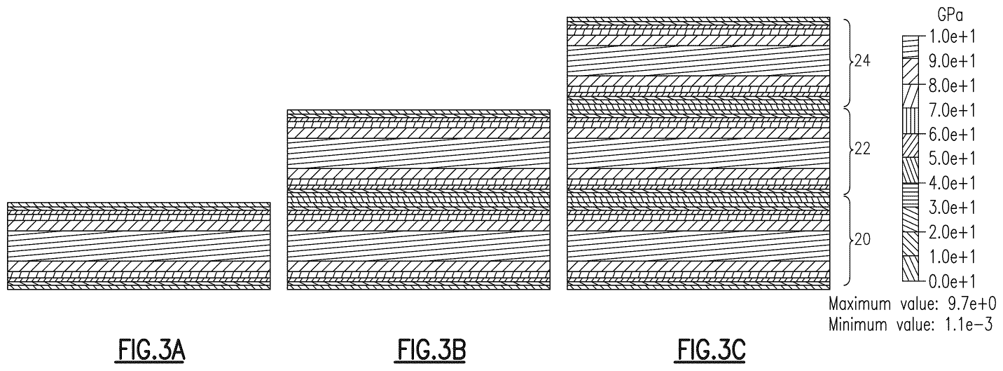

FIG. 3A is a simulated stress distribution map of a first resonator 20. The BAW resonator 1 of FIG. 1 can have the same or similar stress distribution as the first resonator 20 of FIG. 3A. FIG. 3B is a simulated stress distribution map of the first resonator 20 and a second resonator 22 stacked over the first resonator 20. FIG. 3C is a simulated stress distribution map of the first resonator 20, the second resonator 22 stacked over the first resonator 20, and a third resonator 24 stacked over the second resonator 22.

The simulated stress distribution map of FIG. 3A shows that the center of the first piezoelectric layer 28 has the maximum stress and at the surfaces of the first bottom electrode 26a and the first top electrode 26b farthest from the piezoelectric layer 28 have the lowest stress within the first resonator 20. FIGS. 3B and 3C indicate that when the resonators (e.g., the first to third resonators 20, 22, 24) are stacked on one another, the stress distribution within each resonator would be the same as or generally similar to the stress distribution of a single resonator.

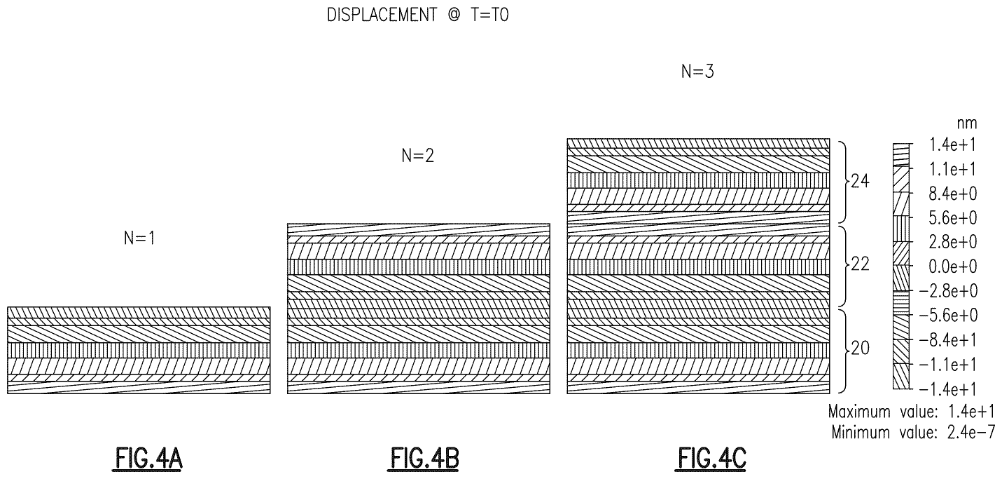

FIG. 4A is a simulated displacement map of a first resonator 20. FIG. 4B is a simulated displacement map of the first resonator 20 and a second resonator 22 stacked over the first resonator 20. FIG. 4C is a simulated displacement map of the first resonator 20, the second resonator 22 stacked over the first resonator 20, and a third resonator 24 stacked over the second resonator 22.

The simulated displacement map of FIG. 4A shows that the center of the first piezoelectric layer 28 has zero or near-zero displacement and at the surfaces of the first bottom electrode 26a and the first top electrode 26b farthest from the piezoelectric layer 28 have the maximum displacement magnitude within the first resonator 20. FIGS. 4B and 4C indicate that when the resonators (e.g., the first to third resonators 20, 22, 24) are stacked on one another, the displacement within each resonator would be the same as or generally similar pattern to the pattern of displacement of a single resonator.

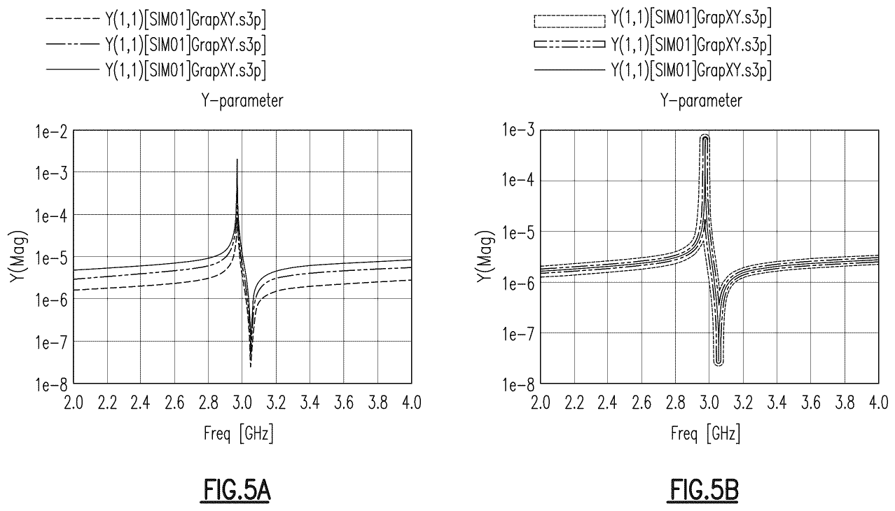

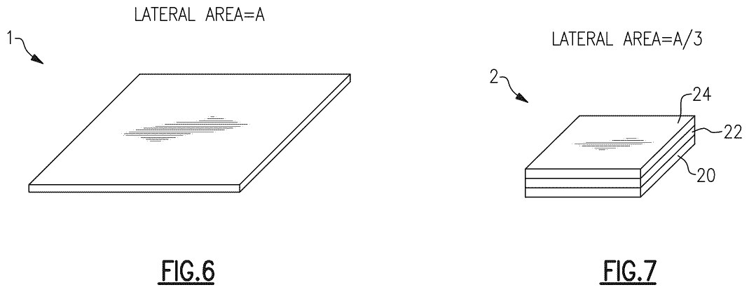

FIG. 5A is a graph showing simulated frequency responses of three BAW devices including a single resonator (e.g., the first resonator 20), a BAW device with two stacked resonators (e.g., the first resonator 20 and the second resonator 22), and a BAW device with three stacked resonators (e.g., the first to third resonators 20, 22, 24). FIG. 5B is a scaled version of FIG. 5A. The simulated frequency responses of FIGS. 5A and 5B indicate that the admittances of the three BAW devices have generally the same shape and generally the same coupling (a difference between the resonance peak and the anti-resonance peak).

FIGS. 6 and 7 show schematic perspective views of the BAW resonator 1 and the BAW device 2 of FIGS. 1 and 2. FIGS. 3A-7 indicate that the BAW device 2 that includes a plurality of vertically stacked resonators (e.g., the first to third resonators 20, 22, 24) can provide the same or generally the similar performance (e.g., the same coupling) as a single resonator, such as the BAW device 1 shown in FIG. 1, with a reduced lateral real estate, area, or dimension. For example, when a BAW device includes n resonators (where n is an integer of two or greater), the lateral area of the BAW device can be n times smaller than the lateral area of a single resonator for accomplishing the same performance. More specifically, when the BAW resonator 1 as shown in FIGS. 1 and 6 and the BAW device 2 with three stacked resonators as shown in FIGS. 2 and 7, are compared, the BAW resonator 1 can have a lateral area A and the BAW device 2 can have a lateral area A/3.

Reduction of the lateral size or dimensions of a BAW device can be beneficial as a smaller lateral size of the BAW device allows for more compact and space-efficient designs, facilitating the integration of BAW devices into significantly smaller electronic components and systems. Increase in the vertical size of the BAW device is less concerning as the relative size scale of the vertical size of the BAW device can be significantly smaller than the scale of the lateral size. For example, a single resonator BAW device (e.g., the BAW resonator 1) can have a width w1 that is in the scale of 25 micrometers (μm) to 200 μm, and a thickness that is in the scale of 1 μm to 2 μm. The ratio between the width w1 and the thickness t1 can be in a range between 200:1 and 25:2. By contrast, a BAW device (e.g., the BAW device 2) with n resonators can have a width w2 that is n² smaller than the width w1 and have an area of the BAW device 2 that is n times smaller than an area of the BAW resonator 1. The width w2 can be less than 100 μm, in some embodiments. In case of a stack of three resonators, for example, the width w2 can be about 70 μm to 120 μm smaller than the width w1 while the thickness t2 is increased only by about 2 μm to 4 μm relative to the thickness t1. In some embodiments, the ratio between the width w2 and the thickness t2 can be, for example, less than 25:1 or less than 50:1. For example, the ratio between the width w2 and the thickness t2 can be in a range between 200/√3:1 and 25/√3:2, 100/√3:1 and 25/√3:2, 50/√3:1 and 25/√3:2, 200/√3:1 and 25/√3:1, or 200/√3:1 and 50/√3:1. A total thickness of a filter can be driven mainly by a substrate thickness and a packaging thickness. Therefore, increasing (e.g., doubling or tripling) the resonator thickness can add negligible thickness to the filter thickness. Any suitable principles and advantages of staked resonators disclosed herein can contribute to including more BAW resonators in a given area and/or to forming a BAW device with a reduced lateral size.

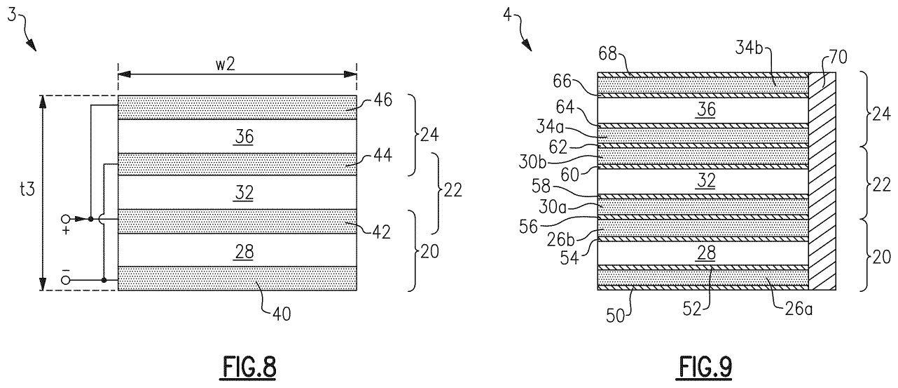

Variations of the BAW device 2 and/or additional features that can be implemented with a BAW device with two or more stacked resonators will be described with respect to FIGS. 8-11. Any suitable combination of the features of the various embodiments disclosed herein can be combined to provide further embodiments.

FIG. 8 is a schematic cross-sectional side view of a BAW device 3 according to an embodiment. Unless otherwise noted, the components of the BAW device 3 shown in FIG. 8 may be structurally and/or functionally the same as or generally similar to like components of other BAW devices disclosed herein. The BAW device 3 is generally similar to the BAW device 2 of FIG. 2A. The BAW device 3 can include a first electrode 40, a second electrode 42, a third electrode 44, a fourth electrode 46, a first piezoelectric layer 28 between the first and second electrodes 40, 42, a second piezoelectric layer 32 between the second and third electrodes 42, 44, and a third piezoelectric layer 36 between the third and fourth electrodes 44, 46. The first electrode 40 can correspond to the first bottom electrode 26a of the BAW device 2, the second electrode 42 can correspond to the first top electrode 26b and the second bottom electrode 30a of the BAW device 2, the third electrode 44 can correspond to the second top electrode 30b and the third bottom electrode 34a of the BAW device 2, and the fourth electrode 46 can correspond to the third top electrode 34b of the BAW device 2.

With the shared electrodes (e.g., the second electrode 42 and the third electrode 44) between the first and second resonators 20, 22, and the second and third resonators 22, 24, a thickness t3 of the BAW device 3 can be smaller than the thickness t2 of the BAW device 2, which can enable further size reduction.

In some applications, unlike the BAW device 3, each resonator of stacked resonators in a BAW device can be isolated from one another (see FIG. 9). Also, heat can be generated during operation of a BAW device, and the generated heat can degrade the performance of the BAW device. One or more temperature compensation structures can be provided to mitigate or prevent performance degradation (see FIG. 9).

FIG. 9 is a schematic cross-sectional side view of a BAW device 4 according to an embodiment. Unless otherwise noted, the components of the BAW device 4 shown in FIG. 9 may be structurally and/or functionally the same as or generally similar to like components of other BAW devices disclosed herein. The BAW device 4 is generally similar to the BAW device 2 of FIG. 2A. In the BAW device 4, layers 50-68 and a temperature compensation structure 70 are provided.

The layer 50 is positioned under the first bottom electrode 26a, the layer 52 is positioned between the first bottom electrode 26a and the first piezoelectric layer 28, the layer 54 is positioned between the first piezoelectric layer 28 and the first top electrode 26b, the layer 56 is positioned between the first top electrode 26b and the second bottom electrode 30a, the layer 58 is positioned between the second bottom electrode 30a and the second piezoelectric layer 32, the layer 60 is positioned between the second piezoelectric layer 32 and the second top electrode 30b, the layer 62 is positioned between the second top electrode 30b and the third bottom electrode 34a, the layer 64 is positioned between the third bottom electrode 34a and the third piezoelectric layer 36, the layer 66 is positioned between the third piezoelectric layer 36 and the third top electrode 34b, and the layer 68 is positioned over the third top electrode 34b. One or more of the layers 50-68 can include a temperature compensation layer, an adhesion layer, a buffer layer, a passivation layer, or a frequency trimming layer. The temperature compensation structure 70 can be in thermal communication with the first to third resonators 20, 22, 24 to dissipate heat generated from the first to third resonators 20, 22, 24.

The layers 50-68 and/or the temperature compensation structure 70 can include silicon oxide (e.g., silicon dioxide (SiO₂)). In some embodiments, the layers 50-68 can direct heat from the heat source to the temperature compensation structure 70. The layers 50-68 can bring the temperature coefficient of frequency (TCF) of the BAW device 4 closer to zero. The layers 50-68 can have a positive TCF. The layers 50-68 can be in physical contact with the first, second, or third piezoelectric layer 28, 32, 36 and/or the electrodes. Any suitable principles and advantages of the BAW devices disclosed herein can be implemented in BAW devices that include a temperature compensation layer.

In some embodiments, the layer 56 can be an isolation layer to isolate the first resonator 20 and the second resonator 22, and the layer 62 can be an isolation layer to isolate the second resonator 22 and the third resonator 34. The isolation layers can include a dielectric material. Isolating the resonators 20, 22, 24 can be beneficial, for example, when the resonators are electrically coupled in series with each other. For example, when the resonators 20, 22, 24 are isolated, the first top electrode 26b and the second bottom electrode 30a can have opposite polarities, the second top electrode 30b and the third bottom electrode 34a can have opposite polarities.

The BAW devices disclosed herein can include a support substrate that supports the stacked resonators and a reflector between the support substrate and the stacked resonators. A BAW device with an air cavity can be referred to as a film bulk acoustic wave resonator (FBAR). A BAW device with a solid acoustic mirror can be referred to as a BAW solidly mounted resonator (SMR).

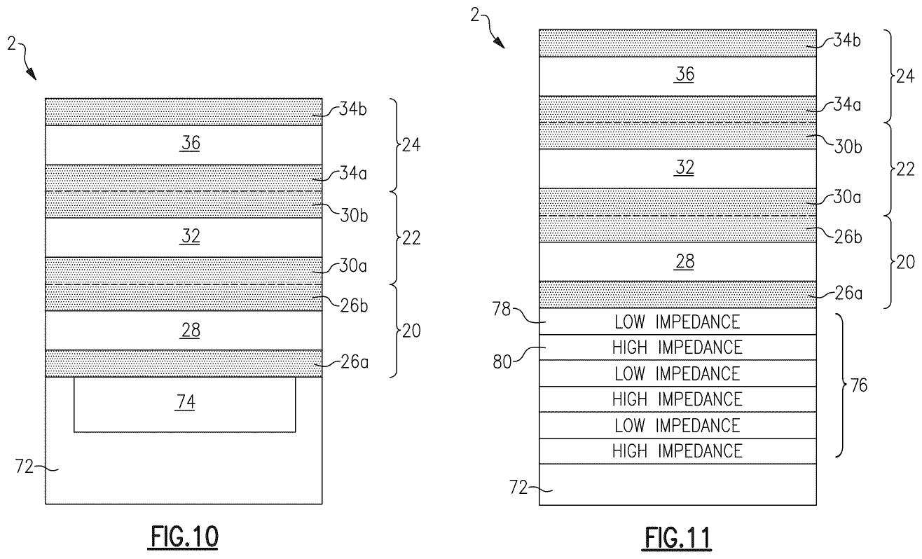

FIG. 10 shows the BAW device 2 as an example of a film bulk acoustic wave resonator (FBAR). FIG. 11 shows the BAW device 2 as an example of a BAW solidly mounted resonator (SMR). The first to third resonators 20, 22, 24 are supported by a support substrate 72. In FIG. 10, there can be a cavity 74 between the support substrate 72 and the first to third resonators 20, 22, 24. In FIG. 11, there can be a solid acoustic mirror 76 between the support substrate 72 and the first to third resonators 20, 22, 24.

The support substrate 72 can be a semiconductor substrate. The support substrate 72 can be a silicon substrate. The support substrate 72 can be any other suitable support substrate, such as a substrate of quartz, silicon carbide, sapphire, glass, gallium arsenide, or any suitable ceramic (e.g., spinel, alumina, etc.). The support substrate 72 can be part of a support structure that includes, for example, the support substrate 72, a trap rich layer (not shown), a passivation layer (not shown), or one or more intermediate layers therebetween (not shown).

The illustrated solid acoustic mirror 76 includes acoustic Bragg reflectors. The illustrated acoustic Bragg reflectors can include alternating low impedance layers 78 and high impedance layers 80. As an example, the Bragg reflectors can include alternating silicon dioxide layers as low impedance layers 78 and tungsten layers as high impedance layers 80. Any other suitable features of an SMR can alternatively or additionally be implemented. Any other suitable features of BAW devices disclosed herein can be implemented in a BAW SMR.

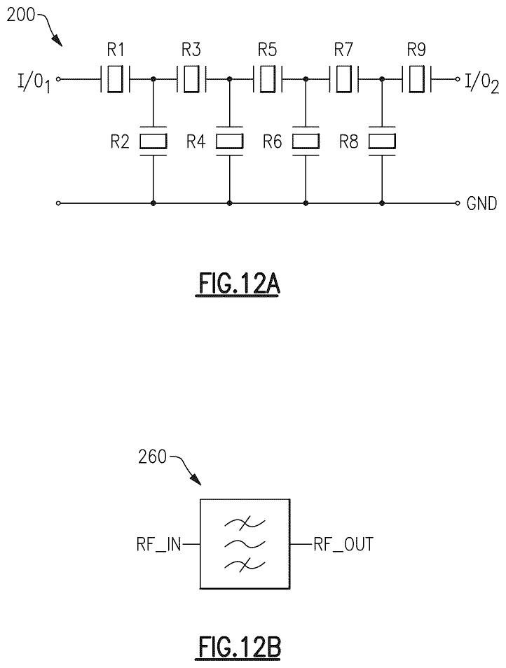

BAW devices disclosed herein can be implemented as BAW resonators in a variety of filters. Such filters can be arranged to filter a radio frequency signal. BAW devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. An example filter topology will be discussed with reference to FIG. 12A.

FIG. 12A is a schematic diagram of a ladder filter 200 that includes an acoustic wave resonator according to an embodiment. The ladder filter 200 is an example topology that can implement a band pass filter formed of acoustic wave resonators. In a band pass filter with a ladder filter topology, the shunt resonators can have lower resonant frequencies than the series resonators. The ladder filter 200 can be arranged to filter a radio frequency signal. As illustrated, the ladder filter 200 includes series acoustic wave resonators R1 R3, R5, R7, and R9 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can be a transmit port and the second input/output port I/O₂ can be an antenna port. Alternatively, the first input/output port I/O₁ can be a receive port and the second input/output port I/O₂ can be an antenna port. One or more of the acoustic wave resonators of the ladder filter 200 can include a BAW resonator in accordance with any suitable principles and advantages disclosed herein. All acoustic resonators of the ladder filter 200 can include a BAW resonator in accordance with any suitable principles and advantages disclosed herein.

A filter that includes a BAW resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that includes an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band.

The BAW resonators disclosed herein can be advantageous for implementing BAW devices with relatively high Qp and relatively low spur intensity. BAW resonators disclosed herein can have significantly better performance than a variety of other BAW resonators. This can be advantageous in meeting demanding specifications for acoustic wave filters, such as performance specifications for certain 5G applications.

FIG. 12B is a schematic diagram of an acoustic wave filter 260. The acoustic wave filter 260 can include the acoustic wave resonators of the ladder filter 200. The acoustic wave filter 260 is a band pass filter. The acoustic wave filter 260 is arranged to filter a radio frequency signal. The acoustic wave filter 260 includes one or more acoustic wave devices coupled between a first input/output port RF_IN and a second input/output port RF_OUT. The acoustic wave filter 260 includes a BAW resonator according to an embodiment.

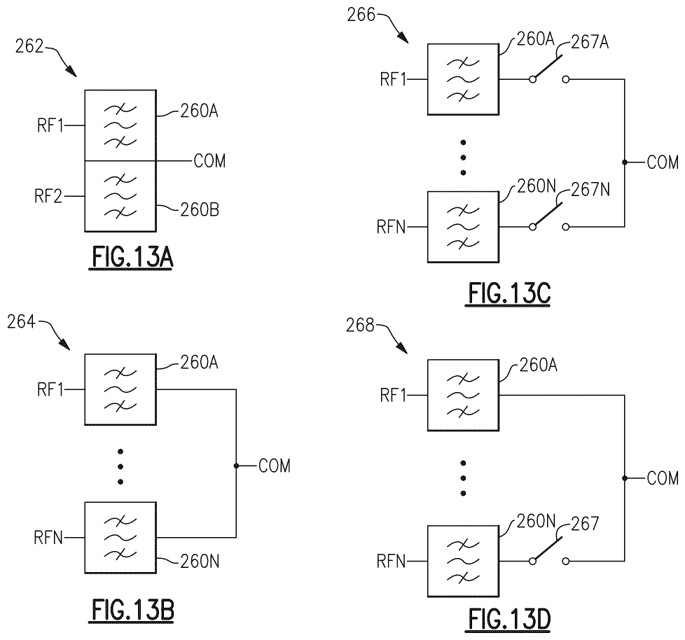

The BAW devices disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 13A to 13D. Any suitable principles and advantages of these multiplexers can be implemented together with each other.

FIG. 13A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A includes a BAW resonator in accordance with any suitable principles and advantages disclosed herein.

The second filter 260B can be any suitable filter arranged to filter a second radio frequency signal. The second filter 260B can be, for example, an acoustic wave filter, an acoustic wave filter that includes a BAW resonator in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 13B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A includes a BAW resonator in accordance with any suitable principles and advantages disclosed herein. The other filter(s) of the multiplexer 264 can include one or more acoustic wave filters, one or more acoustic wave filters that include a BAW resonator in accordance with any suitable principles and advantages disclosed herein, one or more LC filters, one or more hybrid acoustic wave LC filters, the like, or any suitable combination thereof.

FIG. 13C is a schematic diagram of a multiplexer 266 that includes an acoustic wave filter according to an embodiment. The multiplexer 266 is like the multiplexer 264 of FIG. 13B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 13D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

Acoustic wave devices disclosed herein can be implemented in a variety of packaged modules. Some example packaged modules will now be disclosed in which any suitable principles and advantages of the BAW devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 14, 15, and 16 are schematic block diagrams of illustrative packaged modules according to certain embodiments. Any suitable combination of features of these packaged modules can be implemented with each other.

FIG. 14 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW devices in certain applications.

The acoustic wave component 272 shown in FIG. 14 includes one or more acoustic wave devices 274 and terminals 275A and 275B. The one or more acoustic wave devices 274 include one or more BAW devices implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 14. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

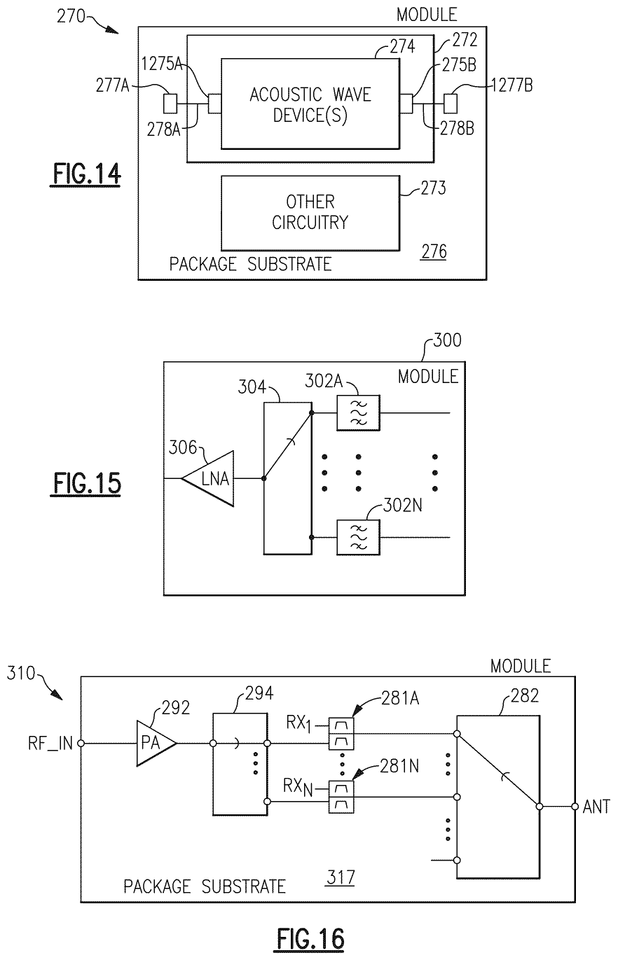

FIG. 15 is a schematic block diagram of a module 300 that includes filters 302A to 302N, a radio frequency switch 304, and a low noise amplifier 306 according to an embodiment. One or more filters of the filters 302A to 302N can include any suitable number of bulk acoustic wave devices in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

FIG. 16 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 16 and/or additional elements. The radio frequency module 310 may include any one of the acoustic wave filters that include at least one bulk acoustic wave resonator in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a BAW device in accordance with any suitable principles and advantages disclosed herein. Similarly, one or more of the receive filters can include a BAW device in accordance with any suitable principles and advantages disclosed herein. Although FIG. 16 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

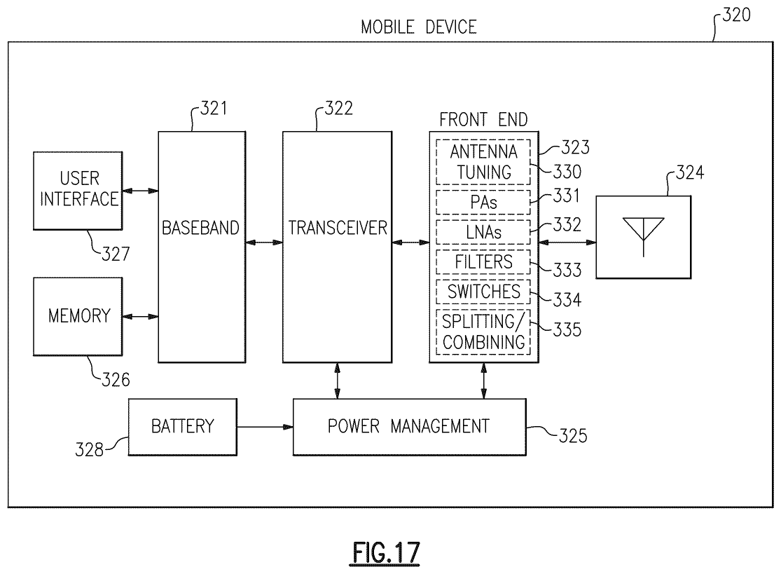

The BAW devices disclosed herein can be implemented in wireless communication devices. FIG. 17 is a schematic block diagram of a wireless communication device 320 that includes a BAW device according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 17 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAs) 331, low noise amplifiers (LNAs) 332, filters 333, switches 334, and signal splitting/combining circuitry 335. However, other implementations are possible. The filters 333 can include one or more acoustic wave filters that include any suitable number of BAW devices in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 17, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 17, the power management system 325 receives a battery voltage from the battery 328. The battery 328 can be any suitable battery for use in the wireless communication device 320, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz, in FR1, in a frequency range from about 2 GHz to 10 GHz, in a frequency range from about 2 GHz to 15 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an car piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device comprising:
a first resonator including a first pair of electrodes and a first piezoelectric layer, the first pair of electrodes having a first top electrode and a first bottom electrode, the first piezoelectric layer positioned between the first top electrode and a first bottom electrode; and
a second resonator including a second pair of electrodes and a second piezoelectric layer, the second pair of electrodes having a second top electrode and a second bottom electrode, the second piezoelectric layer positioned between the second top electrode and a second bottom electrode, the first and second piezoelectric layers positioned between the first bottom electrode and the second top electrode.

2. The bulk acoustic wave device of claim 1 wherein the first bottom electrode and the second top electrode have a first polarity, and the first top electrode and the second bottom electrode have a second polarity opposite from the first polarity.

3. The bulk acoustic wave device of claim 2 wherein the first resonator is electrically connected in parallel with the second resonator.

4. The bulk acoustic wave device of claim 2 wherein a single metal layer includes the first top electrode and the second bottom electrode.

5. The bulk acoustic wave device of claim 1 wherein the first top electrode and the second bottom electrode are physically connected and contiguous.

6. The bulk acoustic wave device of claim 1 wherein the first resonator is electrically connected in series with the second resonator.

7. The bulk acoustic wave device of claim 6 further including an isolation layer between the first resonator and the second resonator.

8. The bulk acoustic wave device of claim 1 wherein the first top electrode and the second bottom electrode are electrically isolated by an isolation layer.

9. The bulk acoustic wave device of claim 1 further comprising a temperature compensation layer coupled with the first piezoelectric layer, wherein the temperature compensation layer configured to dissipate heat generated in the first piezoelectric layer.

10. The bulk acoustic wave device of claim 1 further comprising a third resonator including a third pair of electrodes and a third piezoelectric layer, the second pair of electrodes having a third top electrode and a third bottom electrode, the third bottom electrode positioned between the second piezoelectric layer and the third piezoelectric layer.

11. The bulk acoustic wave device of claim 10 wherein the first resonator, the second resonator, and the third resonator are electrically coupled in parallel with each other.

12. The bulk acoustic wave device of claim 1 wherein the first resonator has a first width and a first thickness, and the second resonator has a second width and a second thickness, a ratio between the first width and a total thickness of the first and second thicknesses is less than 50:1.

13. The bulk acoustic wave device of claim 12 wherein the first width is less than 100 micrometers.

14. A bulk acoustic wave device comprising:
a first resonator including a first piezoelectric layer positioned between a first electrode and a second electrode; and
a second resonator including a second piezoelectric layer positioned between the second electrode and a third electrode.

15. The bulk acoustic wave device of claim 14 wherein the second piezoelectric layer, the second electrode, and the third electrode together define the second resonator.

16. The bulk acoustic wave device of claim 14 further comprising a fourth electrode between the second piezoelectric layer and the second electrode, wherein the second piezoelectric layer, the third electrode, and the fourth electrode together define the second resonator.

17. The bulk acoustic wave device of claim 16 further comprising an isolation layer between the second electrode and the fourth electrode.

18. The bulk acoustic wave device of claim 14 further comprising a third resonator including a third piezoelectric layer positioned between the third electrode and a fourth electrode.

19. The bulk acoustic wave device of claim 18 wherein the first resonator, the second resonator, and the third resonator are electrically coupled in parallel with each other.

20. An acoustic wave filter for filtering a radio frequency signal, the acoustic wave filter comprising:
a bulk acoustic wave device including a first resonator and a second resonator, the first resonator including a first pair of electrodes and a first piezoelectric layer, the first pair of electrodes having a first top electrode and a first bottom electrode, the first piezoelectric layer positioned between the first top electrode and a first bottom electrode, the second resonator including a second pair of electrodes and a second piezoelectric layer, the second pair of electrodes having a second top electrode and a second bottom electrode, the second piezoelectric layer positioned between the second top electrode and a second bottom electrode, the first and second piezoelectric layers positioned between the first bottom electrode and the second top electrode; and
a plurality of additional acoustic wave resonators, the bulk acoustic wave device and the plurality of additional acoustic wave resonators configured to filter the radio frequency signal.
